(19) United States
(12) Patent Application Publication
(10) Pub. No.: US 2024/0005062 A1
(43) Pub. Date: Jan. 4, 2024

(54) METHOD AND SYSTEM FOR PROVIDING DESIGN FEEDBACK

(71) Applicant: IUCF-HYU (INDUSTRY-UNIVERSITY COOPERATION FOUNDATION HANYANG UNIVERSITY), Seoul (KR)

(72) Inventors: Kyung Hoon HYUN, Seoul (KR); Ki Hoon SON, Seoul (KR)

(21) Appl. No.: 18/468,960

(22) Filed: Sep. 18, 2023

Related U.S. Application Data
(63) Continuation of application No. PCT/KR2021/019810, filed on Dec. 24, 2021.

(30) Foreign Application Priority Data
Mar. 18, 2021 (KR) 10-2021-0035293

(51) Int. Cl. G06F 30/20

(52) U.S. Cl. CPC G06F 30/20

(57) ABSTRACT

A method of providing design feedback comprises the steps of: storing design behavior information of a user for a target design; and comparing current design behavior information with previous design behavior information to provide the user with feedback on the current design behavior information, wherein the design behavior information includes at least one of a sketch drawing generated by a design sketch, a design reference search range, and a design reference identified by the user.

### CROSS-REFERENCE TO RELATED APPLICATIONS

This application is a bypass continuation of pending PCT International Application No. PCT/KR2021/019810, which was filed on Dec. 24, 2021, and which claims priority from and the benefit of Korean Patent Application No. 10-2021-0035293, filed with the Korean Intellectual Property Office on Mar. 18, 2021, and all of which are hereby incorporated by reference for all purposes as if fully set forth herein. In addition, when this application also claims priority for countries other than the United States for the same reason as above, all of the contents of the above-listed applications are hereby incorporated by reference.

### TECHNICAL FIELD

The present disclosure relates to a method and system for providing design feedback based on a design move of a user.

### BACKGROUND ART

In the past, designers have performed design by sketching with a pen on a notebook or paper, and even today, many designers are still using such a method. However, when sketching on paper with a pen, it is difficult to edit or change a sketch, and with recent advancements in IT technology, various sketching and drawing applications that run on tablet personal computers (PCs) have developed, and thus more and more designers are sketching using sketching and drawing applications.

In addition, when sketching using a tablet PC or laptop, not only may various design references be searched for through the Internet but also various services required for design may be provided using IT technology, and therefore IT utilization design is expected to gradually grow.

### DISCLOSURE

### Technical Problem

The present disclosure is directed to providing a method and system for providing design feedback capable of supporting the efficient and creative design process of designers.

### Technical Solution

One aspect of the present disclosure provides a method of providing design feedback, the method including: storing design move information of a user for a target design; and comparing previous design move information with current design move information to provide the user with feedback on the current design move information, wherein the design move information includes at least one of a sketch drawing generated by a design sketch, a design reference search range, and a design reference viewed by the user.

Another aspect of the present disclosure provides a method of providing design feedback, the method including: receiving a sketch drawing for a target design; identifying a similarity between design element information of the target design included in the sketch drawing and the design element information included in a design reference; and providing information about the similarity.

### Advantageous Effects

According to one embodiment of the present disclosure, abstract design creativity is quantitatively analyzed to provide the presence/absence of novelty according to a design move of a user as feedback, thereby supporting an efficient and creative design process of designers.

In addition, according to one embodiment of the present disclosure, a user is provided with information about design references similar to a sketch drawing of the user, thereby allowing the user to search for a design reference which can be directly usable for his/her design.

### BRIEF DESCRIPTION OF DRAWINGS

FIG. 1 is a view for describing a system for providing design feedback according to an embodiment of the present disclosure.

FIG. 2 is a view illustrating an example of a sketch drawing for a plane design.

FIG. 3 is a view for describing a method of providing design feedback according to an embodiment of the present disclosure.

FIGS. 4 and 5 are views for describing a method of identifying a novelty according to an embodiment of the present disclosure.

FIG. 6 is a view illustrating an example of micro-feedback according to an embodiment of the present disclosure.

FIGS. 7,8A and 8B are views for describing a method of providing design feedback according to another embodiment of the present disclosure.

### MODES OF THE INVENTION

While embodiments according to the concept of the present disclosure are subject to various modifications and alternative forms, specific embodiments thereof are shown by way of example in the accompanying drawings and will herein be described in detail. However, it should be understood that there is no intent to limit the present disclosure to the particular forms disclosed, rather the present disclosure is to cover all modifications, equivalents, and alternatives falling within the spirit and scope of the present disclosure. In the drawings, like numerals refer to like elements in description of each figure.

Hereinafter, embodiments according to the present disclosure will be described in detail with reference to the accompanying drawings.

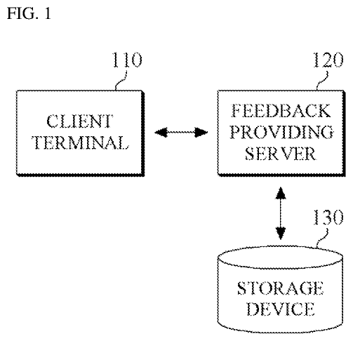

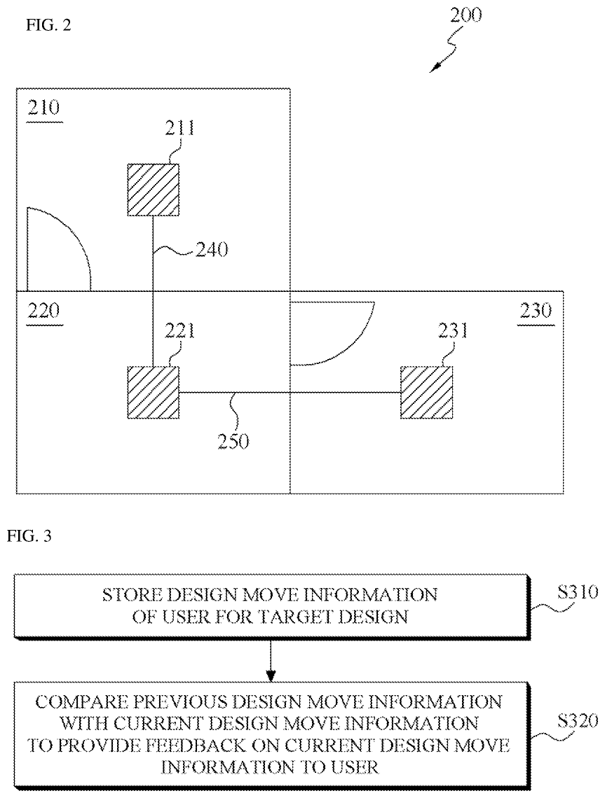

FIG. 1 is a view for describing a system for providing design feedback according to an embodiment of the present disclosure, and FIG. 2 is a view illustrating an example of a sketch drawing for a plane design.

Referring to FIG. 1, the system for providing design feedback according to the embodiment of the present disclosure includes a client terminal 110, a feedback providing server 120, and a storage device 130. Depending on embodiments, the storage device may be included in the feedback providing server 120, and functions of the feedback providing server 120 and the storage device 130 may all be included in the client terminal 110.

The client terminal 110 is a terminal including a processor, a memory, a display, and the like, such as a laptop computer, a desktop personal computer (PC), a mobile terminal, and the like, and a user may sketch a design and search for design references using the client terminal 110.

The client terminal 110 transmits design move information of a user for a target design to the feedback providing server 120. Here, the design move is literally a user's action performed for a design, and includes an action of a user performing a design sketch on the client terminal 110, an action of a user of searching for a design reference using the client terminal 110, and an action of a user of viewing the found design reference on the client terminal 110. In addition, design move information is information about a design move, and includes a sketch drawing generated by a design sketch, a design reference search range, and a design reference viewed by a user among found design references. In addition, the design reference search range may correspond to input information such as a search word input by a user for a design reference search.

The feedback providing server 120 stores the design move information of the user transmitted from the client terminal 110, and provides feedback on the design move information to the user.

The feedback providing server 120 quantitatively analyzes the creativity of a user's design move and provides feedback on design move information, and such feedback may be divided into micro feedback and macro feedback.

Micro-feedback is feedback that indicates whether a novelty is present in current design move information in comparison of previous design move information with the current design move information. The feedback providing server 120 compares current design move information with previous design move information that is different from the current design move information from the viewpoint of at least one piece of design element information included in design move information, and identifies whether a novelty is present in the current design move information. A novel design may be considered a creative design.

Here, design element information is information about design elements constituting a target design, for example, a plane design or a clothing design. As an embodiment, the design element information of the plane design may include the number of rooms, the locations of the rooms, the connectivity between the rooms, and the overall shape of the plane, and the design element information of the clothing design may include a design pattern, a design shape, the type of clothing, and an overall shape of the clothing.

Macro feedback is feedback that indicates a similarity between a sketch drawing of a user and a design reference. The feedback providing server 120 may identify the similarity between the sketch drawing and the design reference for each piece of design element information and provide macro feedback to the user. In addition, the macro feedback also includes feedback indicating whether a novelty is present in current design move information in comparison with previous design move information, which is the same as the current design move information, from the viewpoint of design element information included in design move information.

In addition, the feedback providing server 120 may search for a design reference, among design references stored in the storage device 130, corresponding to input information input by the user for search, and provide the found design reference to the user. For example, as the input information, design element information may be input, and when a user searches for a design reference for a plane design, a search word for the number of rooms or the locations of rooms may be input.

The storage device 130 stores design references and provides the stored design references to the feedback providing server 120. A user's sketch drawing may be a design reference for other users. To identify the similarity of design element information, the design references may be stored in the storage device 130 in a form including design element information.

For example, when the design reference is a sketch drawing for a plane design, the sketch drawing 200 may include tags 211, 221, and 231 representing each room 210, 220, and 230, and include a skeleton composed of straight lines 240 and 250 connecting the tags of the rooms. The number and locations of tags correspond to the number and locations of rooms, and the skeleton represents the connectivity between rooms. In addition, the outline of the plane design corresponds to the overall shape of the plane.

According to one embodiment of the present disclosure, abstract design creativity is quantitatively analyzed to provide the presence/absence of a novelty according to a design move of a user as feedback, thereby supporting an efficient and creative design process of a designer.

In addition, according to one embodiment of the present disclosure, a user is provided with information about design references similar to a sketch drawing of the user, thereby allowing the user to search for a design reference which can be directly usable for his/her design.

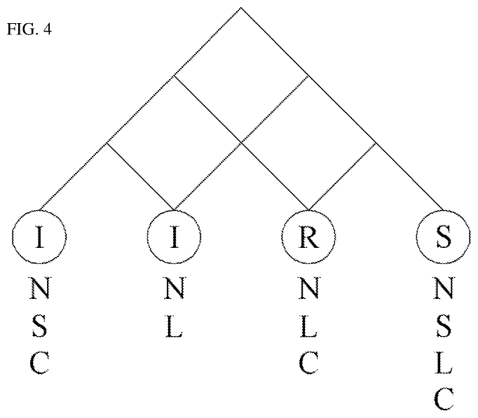

FIG. 3 is a view for describing a method of providing design feedback according to an embodiment of the present disclosure.

The method of providing design feedback according to the embodiment of the present disclosure may be performed in a computing device including a processor and a memory, and in FIG. 3, an embodiment of a method of providing design feedback of the above-described system for providing design feedback is described.

The system for providing design feedback according to the embodiment of the present disclosure stores design move information of a user for a target design (S310). The system for providing design feedback may store design move information input through the client terminal.

Furthermore, the system for providing design feedback according to the embodiment of the present disclosure compares previous design move information with current design move information to provide feedback on the current design move information to the user (S320). As described above, the design move information may include at least one of a sketch drawing generated by a design sketch, a design reference search range, and a design reference viewed by a user.

In addition, the design move information may include at least one piece of design element information of a target design. For example, when a target design is a plane design and the number of rooms, the locations of the rooms, and the overall shape of the plane are included in a sketch drawing, sketch drawing information may include the number of rooms, the locations of the rooms, and the overall shape of the plane as design element information. In addition, when the number of rooms, the connectivity between the rooms, and the overall shape of the plane are used as input information for a design reference search, design reference search range information may include the number of rooms, the connectivity between the rooms, and the overall shape of the plane as design element information. In addition, when a design reference viewed by a user includes the number of rooms, the locations of the rooms, and the connectivity between the rooms, viewed design reference information may include the number of rooms, the locations of the rooms, and the connectivity between the rooms as design element information.

In operation S320, the system for providing design feedback may provide feedback on whether current design move information relative to previous design move information is novel from the viewpoint of each piece of design element information. The system for providing design feedback may identify whether a novelty is present by generating a graph and calculating entropy, and a method of identifying a novelty is described in detail in FIG. 3.

Meanwhile, the system for providing design feedback according to the embodiment of the present disclosure may further include providing a design reference included in a design reference search range among design references stored in the storage device to a user.

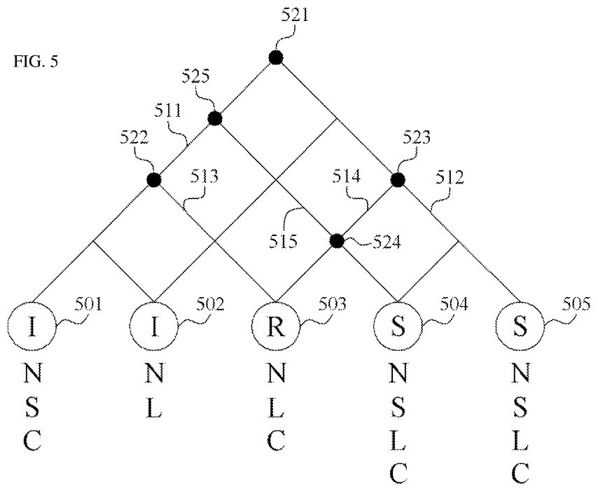

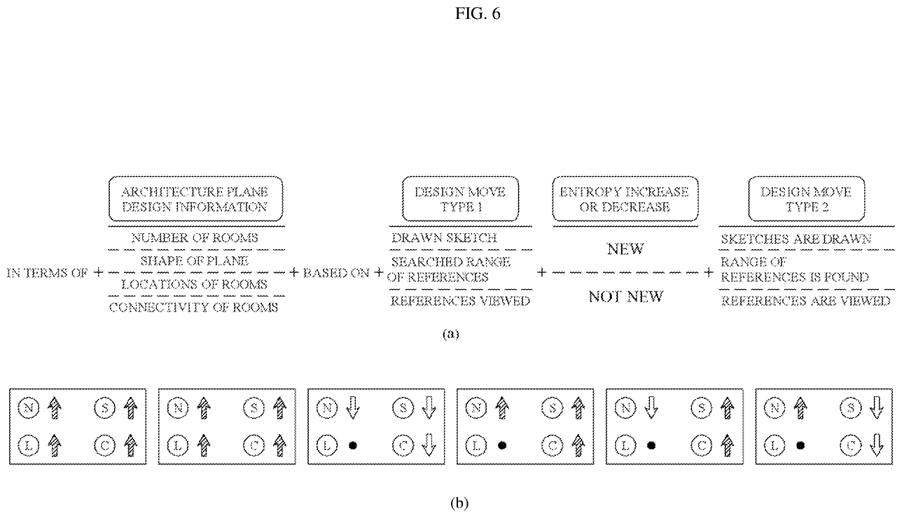

FIGS. 4 and 5 are views for describing a method of identifying novelty according to an embodiment of the present disclosure.

The system for providing design feedback according to the embodiment of the present disclosure generates a graph including nodes representing previous design move information and current design move information and arranged in a linear manner and connection lines of a triangular mesh structure that connect the nodes. As an example, the connection lines of the triangular mesh structure may be generated by drawing connection lines in right diagonal and left diagonal directions at each node and deleting a part of the connection lines in which no connection point is present.

As an example, the system for providing design feedback may generate graphs as shown in FIGS. 4 and 5. The system for providing design feedback updates the graph whenever new design move information is generated, that is, whenever the current design move information is updated, and provides feedback. When design move information is added in a situation in which four pieces of design move information are stored as shown in FIG. 4, the graph may be updated as shown in FIG. An added node may be placed on the right side of the existing node, and in FIG. first to fourth nodes 501 to 504 correspond to previous nodes, and a fifth node 505 corresponds to a current node. In addition, in FIGS. 4 and 5, an S node corresponds to a sketch drawing, an I node corresponds to a design reference search range, and an R node corresponds to a viewed design reference.

The number of intersection points of the connection lines according to the triangular mesh structure corresponds to n(n−1)/2, in which n represents the number of nodes. Since the number of nodes in FIG. 4 is four, the number of intersection points of the connection lines is six, and since the number of nodes in FIG. 5 is five, the number of intersection points of the connection lines is ten.

The system for providing design feedback selects a target node pair including target design element information from among the nodes of the graph after generating the graph. In FIGS. 4 and 5, letters written under nodes represent design element information included in design move information. N represents the number of rooms, S represents the overall shape of the plane, L represents the locations of the rooms, and C represents the connectivity between the rooms.

In this case, the system for providing design feedback may select a target node pair according to the type of feedback. When the provided feedback is micro-feedback, the system for providing design feedback selects two nodes having different design move information as target nodes. In FIG. 5, when target design element information is connectivity C of the rooms, the first and third nodes 501 and 503, the first and fifth nodes 501 and 505, the third and fifth nodes 503 and 505, the first and fourth nodes 501 and 504, and the third and fourth nodes 503 and 504 are selected as target node pairs.

When the provided feedback is macro feedback, two nodes having the same design move information are selected as a target node pair. Hereinafter, a method of identifying a novelty when micro-feedback is provided will be described, and a method of identifying a novelty when macro-feedback is provided is the same as the case in which micro-feedback is provided except for a target node pair.

The system for providing design feedback selects an intersection point, among intersection points of connection lines connecting target node pairs, having a similarity of target design element information greater than or equal to a threshold value as a link. Here, the intersection point corresponds to an intersection point of connection lines starting from each part of a target node pair.

In FIG. 5, connection lines connecting the first node 501 and the fifth node 505, which are a target node pair, are the first connection line 511 and the second connection line 512, and connection lines connecting the first node 501 and the third node 503, which area a target node pair, are the first connection line 511 and the third connection line 513. In addition, connection lines connecting the third node 503 and the fifth node 505, which are a target node pair, are the fourth connection line 514 and the second connection line 512. In addition, connection lines connecting the first node 501 and the fourth node 504, which are a target node pair, are the first connection line 511 and the fifth connection line 515, and connection lines connecting the third node 503 and the fourth node 504, which are a target node pair, are the fourth connection line 514 and the fifth connection line 515.

In addition, there are five intersection points 521, 522, 523, 525, and 525 of the connection lines. The system for providing design feedback identifies the similarity of the connectivity of rooms on the first, third, fourth, and fifth nodes 501, 503, 504, and 505, and for example, when the first and fifth nodes 501 and 505 have a similarity of the connectivity of rooms greater than or equal to a threshold value, a first intersection point 521 is selected as a link among the five intersection points.

In addition, the system for providing design feedback may identify whether a novelty is present by calculating entropy using the number of intersection points and the number of links. As an embodiment, entropy may be calculated from the ratio of the number of links to the number of intersection points, and when the ratio value is larger, the possibility of being novel is higher.

The system for providing design feedback may calculate entropy by summating the ratio value of the number of links to the number of intersection points in each of the first connection line 511 and the second connection line 512 connecting the target nodes corresponding to the first intersection point 521 selected as a link, and the ratio value of the number of links to the number of intersection points included in a group of intersection points including a link among groups of intersection points arranged in a line in parallel with the nodes.

As an example, the system for providing design feedback may calculate entropy H using [Equation 1].

H=−P(on)log₂P(on)−P(off)log₂P(off),P(on)+P(off)=1 [Equation 1]

Here, P(on) is the ratio value of the number of links to the total number of intersection points of a connection line or a group of intersection points, and P(off) is the ratio value of the number of intersections that are not links to the total number of intersection points of a connection line or a group of intersection points. Further, the connection line or the group of intersection points corresponds to a connection line or a group of intersection points including two or more intersection points.

For example, in the first connection line 511 and the second connection line 512, the total number of intersection points is four, and the number of links among the intersection points is one, and thus P(on) in the first connection line 511 and the second connection line 512 is ¼, and P(off) is ¾. The system for providing design feedback may apply the above described calculated ratio values to Equation 1 and perform summation to calculate the final entropy. In the embodiment of FIG. 5, an entropy for the current sketch drawing prepared based on a design reference range having been searched for from the viewpoint of the connectivity of the rooms may be calculated.

The system for providing design feedback compares the entropy value of the previous sketch drawing based on the design reference range that has been searched for from the viewpoint of the connectivity of rooms derived from the graph of FIG. 4 and the entropy value for the current sketch drawing, and when the entropy value for the current sketch drawing is higher than the entropy value for the previous sketch drawing, identifies that a novelty is present, and when the entropy value for the current sketch drawing is lower than the entropy value for the previous sketch drawing, identifies that a novelty is not present. That is, the system for providing design feedback may identify whether a novelty is present according to whether the ratio of the number of links to the number of intersection points increases or decreases.

According to an embodiment, the system for providing design feedback may select a node for design move information selected by a user, among nodes including target design element information, as a target node pair. For example, when the user desires to receive feedback on the current sketch drawing S prepared based on a design reference range I having been searched for by the user, the system for providing design feedback may select a target node pair among the first, fourth and fifth nodes 501, 504, and 505.

The system for providing design feedback according to the embodiment of the present disclosure selects a target node pair for each piece of target design element information and calculates entropy as described above, thereby providing feedback on whether the current design move is novel relative to the previous design move information from the viewpoint of each piece of design element information.

Meanwhile, the similarity between the above described pieces of design element information may be calculated in various ways. For example, the number of rooms may be calculated such that the similarity increases as the difference in the numbers of rooms is smaller, and the locations of the rooms may be calculated such that the similarity increases as the difference in locations of tags included in the rooms is smaller. In addition, the similarity of the connectivity between the rooms may be calculated according to the difference in the shapes of the skeleton, and the similarity of the overall shape of the plane may be calculated according to the difference in the outline shapes of the sketch. As an example, the similarity of the skeleton and the outer shape of the sketch may be derived by overlapping a lattice-shaped box on the skeleton and the outer shape of the sketch, and then calculating a proportion of the skeleton and the outer shape of the sketch that overlap the box in each lattice.

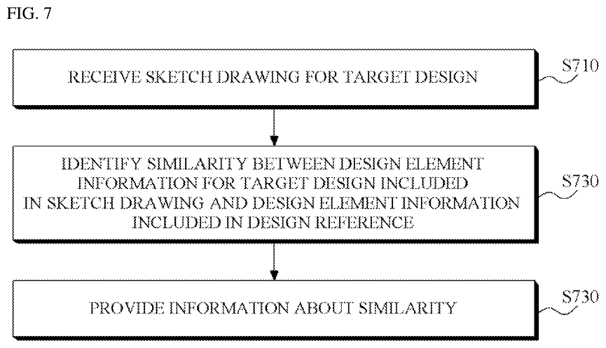

FIG. 6 is a view illustrating an example of micro-feedback according to an embodiment of the present disclosure.

Referring to FIG. 6, micro-feedback may be provided in the form of text (a) or in the form of arrows (b) indicating an increase or decrease in entropy.

In response to a novelty being present in the above-described embodiment of FIG. 5, the system for providing design feedback may provide text “In terms of the connectivity between the rooms, you drew a new sketch based on the searched range of design references.” as feedback on the current design move information. On the other hand, in response to a novelty not being present in the above-described embodiment of FIG. 5, the system for providing design feedback may provide text “In terms of the connectivity between the rooms, you drew a sketch that is not new based on the searched range of design references.” as feedback on the current design move information.

When the target design element information is the number of rooms and the current design move information is the design reference search range, micro-feedback may be, for example, “In terms of the number of rooms, you found a new range of references based on the drawn sketches.”

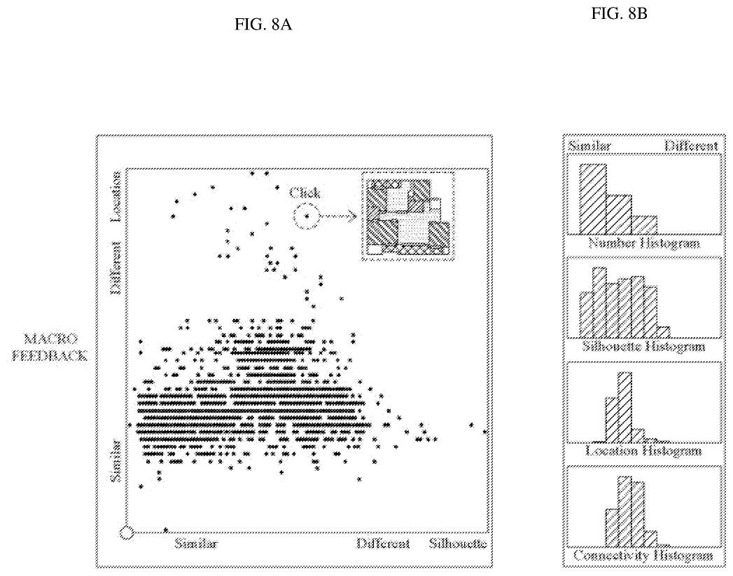

FIGS. 7 and 8 are views for describing a method of providing design feedback according to another embodiment of the present disclosure, in which FIG. 7 is a flowchart of a method of providing design feedback, FIG. 8A is a view illustrating a scatter plot provided as macro feedback, and FIG. 8B is a view illustrating a histogram provided as micro-feedback.

A system for providing design feedback according to an embodiment of the present disclosure receives a sketch drawing of a target design (S710), and identifies the similarity between design element information for the target design included in the sketch drawing and design element information included in a design reference (S720).

For example, when the target design is a plane design, the system for providing design feedback identifies the similarity between each of the number of rooms included in the sketch drawing, the locations of the rooms, the connectivity between the rooms, and the overall shape of the plane and each of the number of rooms included in the design reference, the locations of the rooms, the connectivity between the rooms, and the overall shape of the plane. That is, the identification of a similarity is performed for each piece of design element information.

In addition, the system for providing design feedback provides information about the similarity identified in operation S720 (S730).

As an embodiment, the system for providing design feedback may provide the information about the similarity using a scatter plot. In this case, the system for providing design feedback classifies the design references stored in the storage device according to the similarity of design element information selected from among pieces of design element information, and generates a scatter plot for the classified design references.

The scatter plot may be generated on a two-dimensional plane as shown in FIG. 8A, and the x-axis and y-axis correspond to the overall shape (silhouette) of the plane and the locations of the rooms, which are design element information selected by the user. In addition, the reference designs classified according to the similarity of the selected design element information are expressed as points on the scatter plot. The farther the point is from the origin, the lower the similarity between the sketch drawing and the design reference for the selected design element information.

The system for providing design feedback may, in response to a point displayed on the scatter plot and corresponding to a design reference being selected by clicking or the like, output the design reference corresponding to the selected point.

As another embodiment, the system for providing design feedback may provide the information about the similarity using a histogram. In this case, the system for providing design feedback may classify the design references stored in the storage device according to the similarity and generate a histogram indicating the number of the classified design references.

As shown in FIG. 8B, the histogram may be generated for each piece of design element information. In the histogram, the x-axis represents the magnitude of the similarity, and the y-axis represents the number of design references. The width of the bar graph is determined according to the range of the similarity, and the range of the similarity may be freely adjusted by the user.

The technical details described above can be implemented in the form of program instructions executable by a variety of computer devices and may be recorded on a computer readable medium. The computer readable medium may include, alone or in combination, program instructions, data files and data structures. The program instructions recorded on the computer readable medium may be components specially designed for the present disclosure or may be usable by a skilled person in the field of computer software. Computer readable record media include magnetic media such as a hard disk, a floppy disk, or a magnetic tape, optical media such as a compact disc read only memory (CD-ROM) or a digital video disc (DVD), magneto-optical media such as floptical disks, and hardware devices such as a ROM, a random-access memory (RAM), or a flash memory specially designed to store and execute programs. Examples of the program instructions include not only machine language code made by a compiler but also high level code that can be used by an interpreter etc., which is executed by a computer. The hardware device may be configured to act as one or more software modules in order to perform the operations of the present disclosure, or vice versa.

While the disclosure has been shown and described with respect to particulars, such as specific components, embodiments, and drawings, the embodiments are used to aid in the understanding of the present disclosure rather than limiting the present disclosure, and those skilled in the art should appreciate that various changes and modifications are possible without departing from the spirit and scope of the disclosure. Therefore, the spirit of the present disclosure is not defined by the above embodiments but by the appended claims of the present disclosure, and the scope of the present disclosure is to cover not only the following claims but also all modifications and equivalents derived from the claims.

What is claimed is:

1. A method of providing design feedback, the method comprising:
storing design move information of a user for a target design; and
comparing previous design move information with current design move information to provide the user with feedback on the current design move information,
wherein the design move information includes at least one of a sketch drawing generated by a design sketch, a design reference search range, and a design reference viewed by the user.

2. The method of claim 1, wherein the design move information includes at least one piece of design element information of the target design,
wherein the providing of the feedback includes, from the viewpoint of each piece of design element information,
providing the feedback on whether the current design move information is novel relative to the previous design move information.

3. The method of claim 2, wherein the providing of the feedback includes:
generating a graph including nodes representing the previous design move information and the current design move information and arranged in a linear manner, and connection lines of a triangular mesh structure that connect the nodes;
selecting a target node pair including target design element information from among the nodes;
selecting an intersection point among intersection points of the connection lines connecting the target node pairs having a similarity of the target design element information greater than or equal to a threshold value as a link; and
identifying whether the current design move information is novel using a number of the intersection points and a number of links.

4. The method of claim 3, wherein the identifying of whether the current design move information is novel includes identifying whether the current design move information is novel depending on whether a ratio of the number of the links to the number of the intersection points increases or decreases.

5. The method of claim 3, wherein the selecting of the target node pair includes selecting two nodes having the same design move information or two nodes having different design move information as the target node pair.

6. The method of claim 2, wherein the target design is a plane design, and
the design element information for the plane design includes a number of rooms, locations of the rooms, connectivity between the rooms, and an overall shape of a plane.

7. The method of claim 1, further comprising providing the user with a design reference, among design references stored in a storage device, which is included in the design reference search range.

8. The method of claim 1, wherein the providing of the feedback includes providing the feedback whenever the current design move information is updated.

9. A method of providing design feedback, the method comprising:
receiving a sketch drawing for a target design;
identifying a similarity between design element information of the target design included in the sketch drawing and the design element information included in a design reference; and
providing information about the similarity.

10. The method of claim 9, wherein the providing of the information about the similarity includes:
classifying design references stored in a storage device according to the similarity; and
generating a histogram representing a number of the classified design references.

11. The method of claim 9, wherein the providing of the information about the similarity includes:
classifying design references stored in a storage device according to a similarity of information selected from among the design element information; and
generating a scatter plot for the classified design references.

12. The method of claim 11, further comprising, in response to a point displayed on the scatter plot and corresponding to the design reference being selected, outputting the design reference corresponding to the point.
